(19) United States
(12) Patent Application Publication
(10) Pub. No.: US 2025/0220981 A1
(43) Pub. Date: Jul. 3, 2025

(54) SOURCE/DRAIN STRUCTURE FOR SEMICONDUCTOR DEVICES AND MANUFACTURING METHODS THEREOF

(71) Applicant: Taiwan Semiconductor Manufacturing Company, Ltd., Hsin-Chu (TW)

(72) Inventors: Shih-Hao Lin, Hsinchu (TW); Wei Hao Lu, Taoyuan City (TW); Chih-Hsiang Huang, Zhubei City (TW)

(21) Appl. No.: 18/677,120

(22) Filed: May 29, 2024

Related U.S. Application Data
(60) Provisional application No. 63/615,152, filed on Dec. 27, 2023.

(51) Int. Cl. H01L 29/78; H01L 29/06; H01L 29/08; H01L 29/423; H01L 29/66; H01L 29/775; H01L 29/786

(52) U.S. Cl. CPC H10D 30/797; H10D 30/014; H10D 30/43; H10D 30/6735; H10D 30/6757; H10D 62/121; H10D 62/151; H10D 64/017

(57) ABSTRACT

The present disclosure provides a semiconductor device and a method of forming the same. A method according to one embodiment of the present disclosure includes forming a stack of channel layers interleaved by sacrificial layers over a substrate, patterning the stack to form a fin-shape structure, forming a dummy gate stack over the fin-shape structure, recessing the fin-shape structure to form a source/drain trench, partially recessing the sacrificial layers to form inner spacer recesses, forming inner spacers in the inner spacer recesses, selectively depositing a segregation preventing layer on surfaces of the inner spacers, and forming an epitaxial feature in the source/drain trench. The surfaces of the inner spacers include a first surface exposed in the source/drain trench and a second surface facing an adjacent one of the channel layers. A portion of the segregation preventing layer is stacked between the inner spacers and the epitaxial feature.

### PRIORITY DATA

This application claims priority to U.S. Provisional Patent Application No. 63/615,152, filed on Dec. 27, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

To improve performance of a multi-gate transistor, including a FinFET transistor or an MBC transistor, efforts are invested to develop a proper source/drain structure that strains channels and provides reduced resistance. While conventional source/drain structures are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5, 6, 7, 8, 9, 10, 11, 12, 13, 14, 15, 16, 17, 18, 19, 20, 21, and 22 illustrate fragmentary cross-sectional views of a workpiece during a fabrication process according to the method of FIG. 1, according to one or more aspects of the present disclosure.

FIGS. 23A, 23B, 23C, and 23D illustrate fragmentary cross-sectional views of alternative embodiments of the workpiece, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to structures in source/drain regions of multi-gate transistors in retarding phosphorus segregation. The term “phosphorus segregation” refers to a phenomenon where phosphorus atoms cluster or segregate in certain regions and become unable to provide electrons as carriers. Phosphorus atoms in segregation are no longer considered as active phosphorus atoms but inactive (or clustered, or segregated) phosphorus atoms, as these atoms lose the ability to contribute electrons as carriers. When phosphorus atoms as dopants in epitaxial features out diffuse from the doped source/drain regions to the channel region of a transistor, the phosphorus atoms may come into contact with neighboring nitride-containing dielectric features, such as surfaces of nitride-containing inner spacers and/or gate spacers, leading to phosphorus clustering and resulting in “phosphorus segregation”. Phosphorus segregation causes decreased active phosphorus concentration and thus degrades drive current in the transistor.

The following disclosure will continue with one or more MBC transistor examples to illustrate various embodiments of the present disclosure. It is understood, however, that the application should not be limited to a particular type of device, except as specifically claimed. For example, aspects of the present disclosure may also apply to implementation based on FinFET transistors. Channel regions of an MBC transistor may be disposed in nanowire channel members, bar-shaped channel members, nanosheet channel members, nanostructure channel members, column-shaped channel members, post-shaped channel members, and/or other suitable channel configurations. Depending on the shapes of the channel members, MBC transistors may also be referred to as nanowire transistors or nanosheet transistors. Despite of the shapes, channel members of an MBC transistor may also be referred to as nanostructures. Each of the channel members extend between and are coupled to two epitaxial features in two opposing source/drain regions. The epitaxial features are also referred to as source/drain features, or source/drain epitaxial features. Source/drain region(s) may refer to a source or a drain, individually or collectively dependent upon the context.

Source/drain features of an MBC transistor introduce strain on the channel members and provide low resistance. Dopants in the source/drain features may diffuse into the end portions of the channel members, forming a lightly doped region, also referred to as the source/drain extension (SDE) region or LDD region. For n-type transistors, the source/drain features may be doped with dopants such as phosphorus (P) or arsenic (As). Generally, source/drain features are in contact with gate spacers and inner spacers of the MBC transistor. Phosphorus atoms diffused into the SDE regions may come into contact with surfaces of the gate spacers and inner spacers and be trapped by dangling bonds extended from these surfaces particularly when the gate spacers and inner spacers include a nitride, causing phosphorus segregation. Phosphorus segregation creates an uneven junction profile between a source/drain region and a channel region and increases source/drain resistance, which may deteriorate n-type transistor performance.

The present disclosure provides embodiments of a semiconductor device where a segregation preventing layer is formed on surfaces of the inner spacers and/or gate spacers to retard phosphorus segregation. That is, the segregation preventing layer controls the extent to which the phosphorus atoms being trapped by the dangling bonds extended from the surfaces of a nitride-containing dielectric surface of the inner spacers and/or gate spacers. In some embodiments, the segregation preventing layer is an arsenic-containing layer, such as a film essentially made of arsenic atoms in a two-dimensional (2-D) lattice of a single atomic layer or a stack of multiple atomic layers, or a layer composed of an arsenic-containing compound comprising silicon, nitrogen, and arsenic. The segregation preventing layer leads to a more even junction profile between a source/drain region and a channel region and reduces source/drain resistance by providing more active phosphorus atoms in the SDE regions.

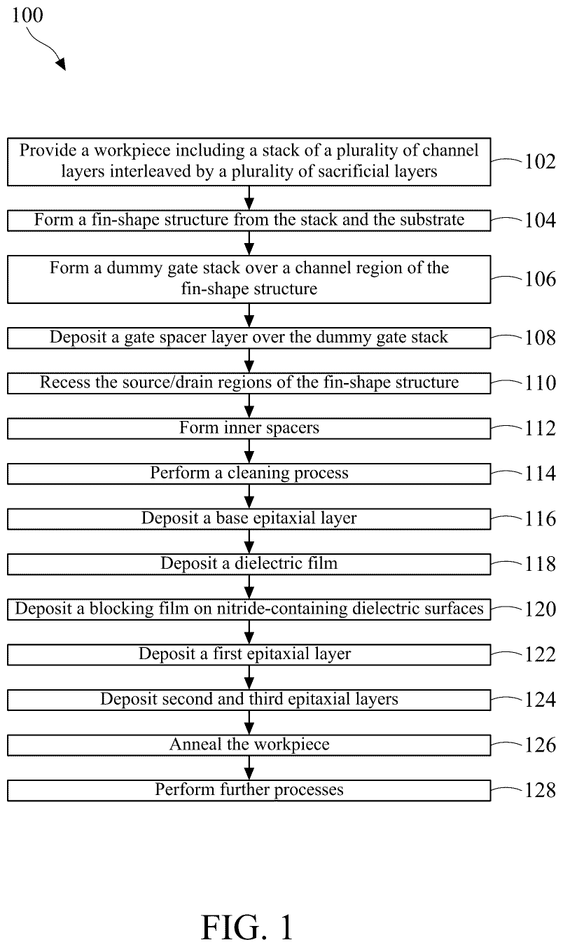

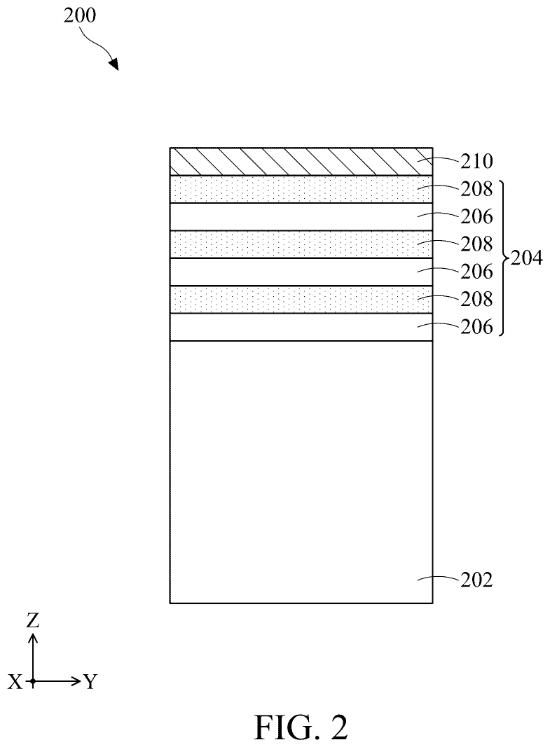

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-22, which are fragmentary cross-sectional views of a workpiece 200 at different stages of fabrication according to embodiments of the method 100 in FIG. 1. Because the workpiece 200 will be fabricated into a semiconductor device, the workpiece 200 may be referred to herein as a semiconductor device (or device) 200 as the context requires. For avoidance, the X, Y and Z directions in FIGS. 2-22 are perpendicular to one another. Throughout the present disclosure, like reference numerals denote like features, unless otherwise excepted.

Referring to FIGS. 1 and 2, method 100 includes a block 102 where a stack 204 of alternating semiconductor layers is formed over the workpiece 200. As shown in FIG. 2, the workpiece 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the n-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 1 and 20.

In some embodiments, all sacrificial layers 206 may have a substantially uniform first thickness between about 3 nm and about 10 nm and all of the channel layers 208 may have a substantially uniform second thickness between about 3 nm and about 15 nm. The first thickness and the second thickness may be the same or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204. In some implementations, the top surface of the substrate 202 is in a (100) crystalline plane, and accordingly each layer of the stack 204 has a (100) top surface. In some alternative implementations, the top surface of the substrate is in a (110) crystalline plane, and accordingly each layer of the stack 204 has a (110) top surface.

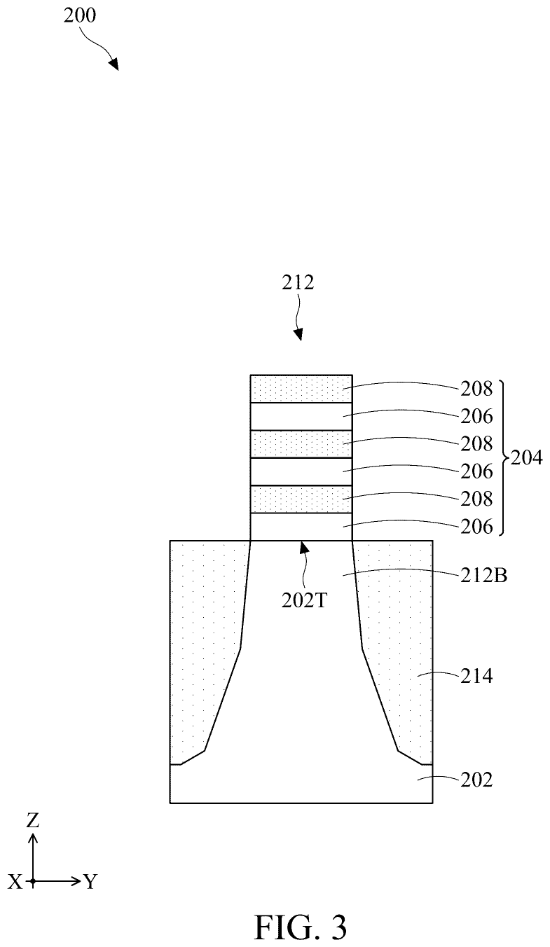

Referring to FIGS. 1, 2, and 3, method 100 includes a block 104 where a fin-shape structure 212 is formed from patterning the stack 204 and a top portion of the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shape structure 212 may be patterned from the stack 204 and a top portion of the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. The etch process at block 104 forms trenches extending through the stack 204 and a portion of the substrate 202. The trenches define the fin-shape structures 212. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shape structure 212 by etching the stack 204 and a top portion of the substrate 202. The patterned top portion of the substrate 202 is also denoted as a fin-shape base 212B. A horizontal plane comprising an interface between the stack 204 and the fin-shape base 212B is denoted as the plane 202T, which marks a position of the bottom surface of the stack 204 and/or the top surface of the fin-shape base 212B. The fin-shape base 212B may still be considered as a top part of the substrate 202 as the context requires. Therefore, the plane 202T may also be considered as marking a position of the top surface of the substrate 202. As shown in FIG. 3, the fin-shape structure 212, which includes the patterned stack 204 and the fin-shape base 212B, extends vertically along the Z direction and lengthwise along the X direction. In some instances, the fin-shape structure 212 measures between about 6 nm and about 80 nm wide along the Y direction, and a distance between opposing sidewalls of two adjacent fin-shape structures 212 measures between about 6 nm and about 115 nm along the Y direction.

An isolation feature 214 is formed adjacent the fin-shape structure 212. In some embodiments, the isolation feature 214 may be formed in the trenches to isolate the fin-shape structures 212 from a neighboring active region. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. The fin-shape structure 212 rises above the STI feature 214 after the recessing. The recessed top surface of the STI feature 214 may be leveled with the plane 202T or below the plane 202T.

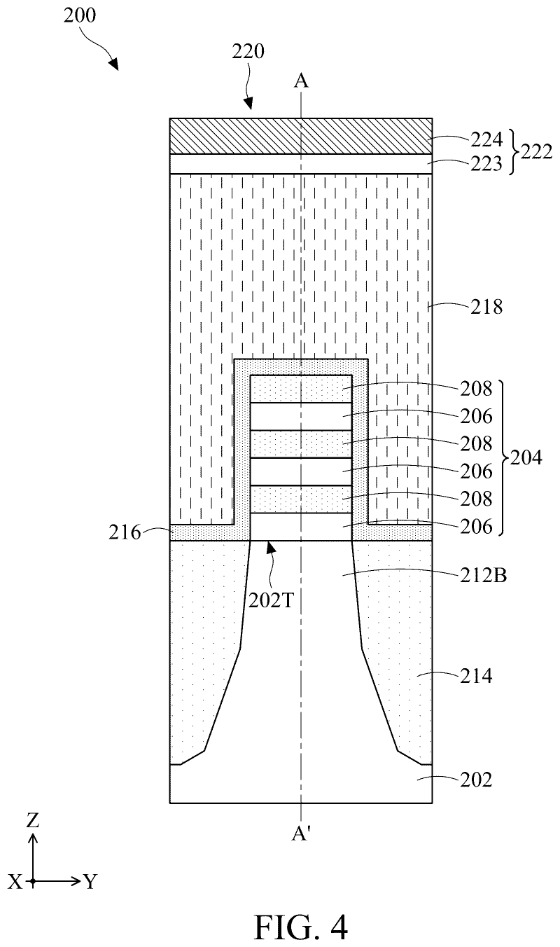

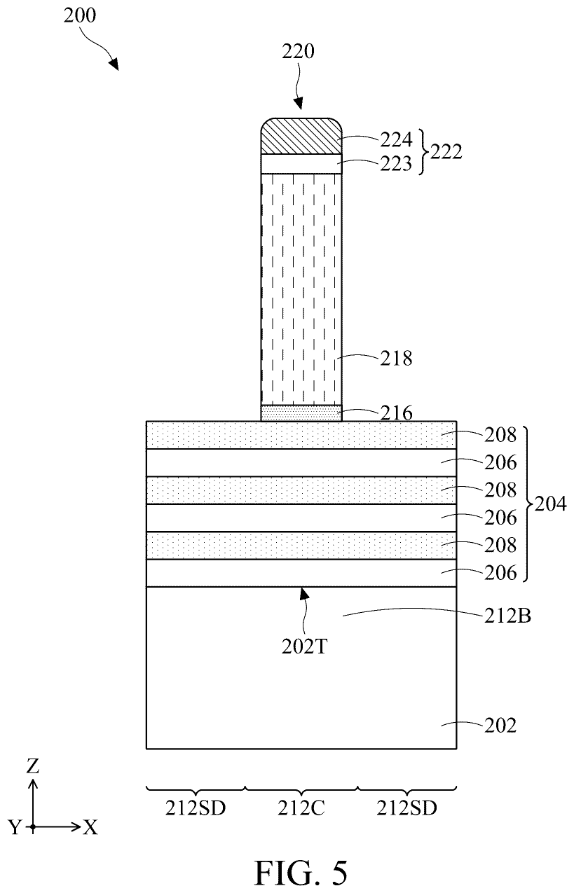

Referring to FIGS. 1, 4, and 5, method 100 includes a block 106 where a dummy gate stack 220 is formed over a channel region 212C of the fin-shape structure 212. FIG. 5 is a cross-sectional view cut through A-A′ line in FIG. 4. In some embodiments, a gate replacement process (or gate-last process) is adopted where the dummy gate stack 220 (shown in FIGS. 4 and 5) serves as a placeholder to undergo various processes and is to be removed and replaced by the functional gate structure. Other processes and configuration are possible. In some embodiments illustrated in FIG. 5, the dummy gate stack 220 is formed over the fin-shape structure 212 and the fin-shape structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the workpiece 200. In some embodiments, the dummy dielectric layer 216 may be formed on the fin-shape structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, no dummy gate stack 220 is disposed over the source/drain region 212SD of the fin-shape structure 212.

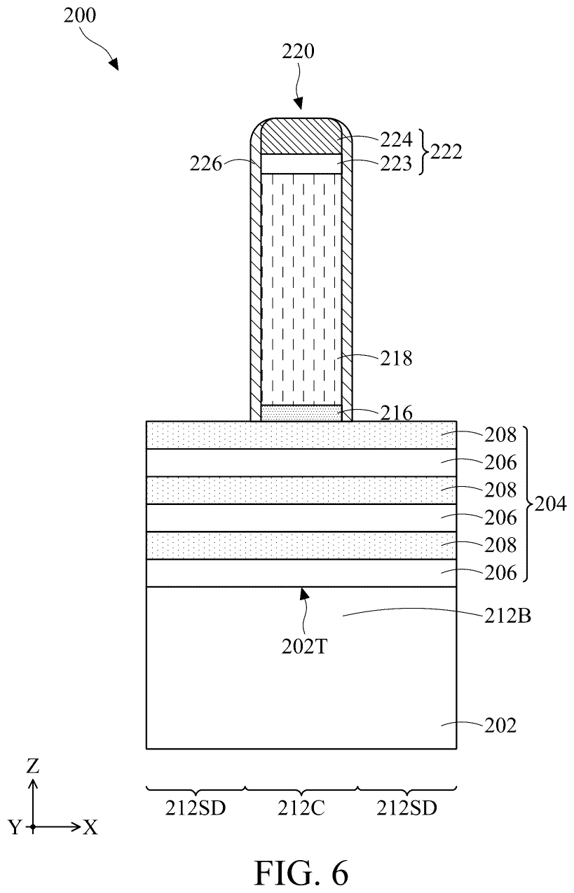

Referring to FIGS. 1 and 6, method 100 includes a block 108 where gate spacers 226 is deposited over the dummy gate stack 220. In some embodiments, the gate spacers 226 are deposited conformally over the workpiece 200, including over top surface and sidewalls of the dummy gate stack 220. The term “conformally” may be used herein for ease of description of a layer having substantially uniform thickness over various regions. The gate spacers 226 may be a single layer or a multi-layer. In some embodiments, at least one layer in the gate spacers 226 may include a nitride, such as silicon nitride, silicon oxynitride, silicon carbonitride, or silicon oxycarbonitride. The gate spacers 226 may be deposited over the dummy gate stack 220 using processes such as, a CVD process, a subatmospheric CVD (SACVD) process, an ALD process, or other suitable process. In one embodiment, the gate spacers 226 includes a first layer and a second layer disposed over the first layer. The first layer may include silicon oxynitride and the second layer may include silicon nitride. In some instances, the gate spacers 226 measure between about 3 nm and about 8 nm thick along the X direction.

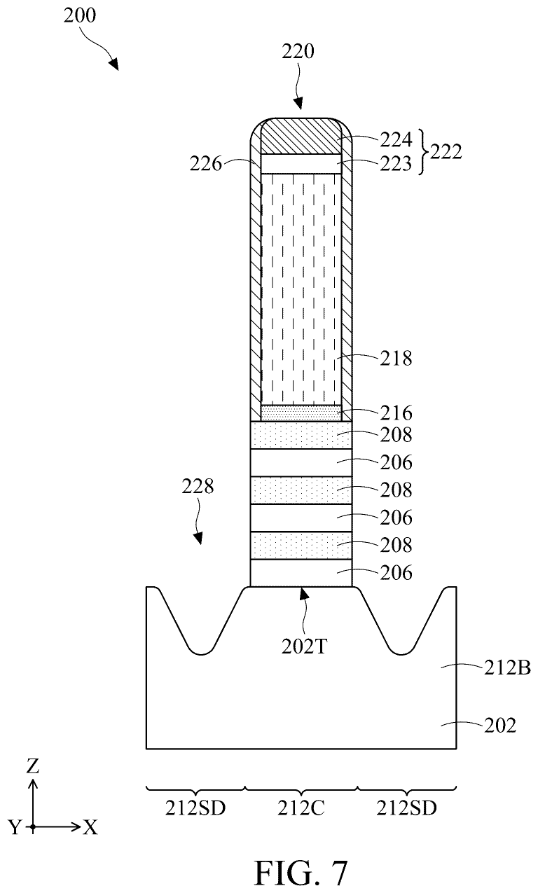

Referring to FIGS. 1 and 7, method 100 includes a block 110 where a source/drain region 212SD of the fin-shape structure 212 is recessed to form a source/drain trench 228. In some embodiments, the source/drain regions 212SD that are not covered by the dummy gate stack 220 and the gate spacers 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some embodiments represented in FIG. 7, the source/drain regions 212SD of the fin-shape structure 212 are recessed to expose sidewalls of the sacrificial layers 206 and the channel layers 208. In some implementations, the source/drain trenches 228 extend below the stack 204 into the substrate 202 (below the plane 202T). As shown in FIG. 7, the sacrificial layers 206 and channel layers 208 in the source/drain region 212SD are removed at block 110, exposing the substrate 202.

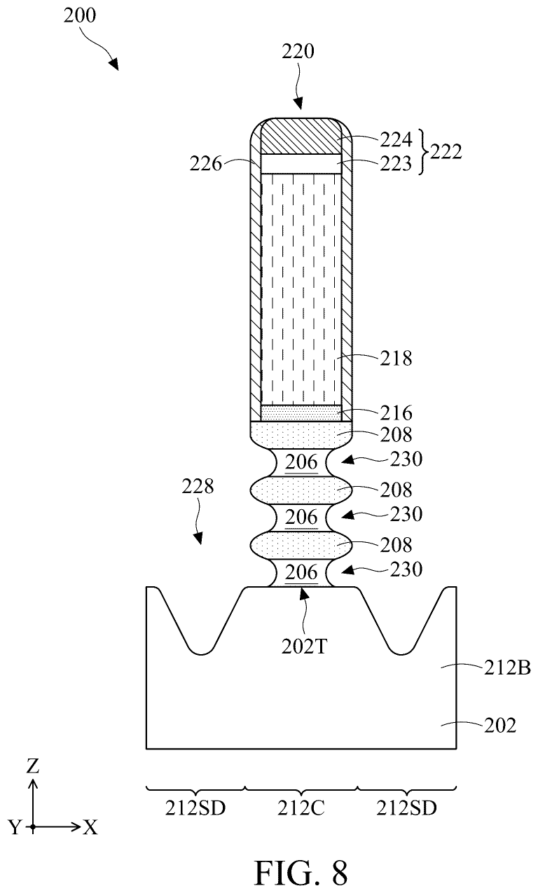

Referring to FIGS. 1, 8, 9, and 10, method 100 includes a block 112 where inner spacers 234 are formed. While not shown explicitly, operation at block 112 may include selective and partial removal of the sacrificial layers 206 to form inner spacer recesses 230, deposition of inner spacer material 232 over the workpiece 200, and etch back the inner spacer material 232 to form inner spacers 234 in the inner spacer recesses 230. The sacrificial layers 206 exposed in the source/drain trenches 228 (shown in FIG. 8) are selectively and partially recessed to form inner spacer recesses 230 while the gate spacers 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. The selective and partial recess of the sacrificial layers 206 may include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

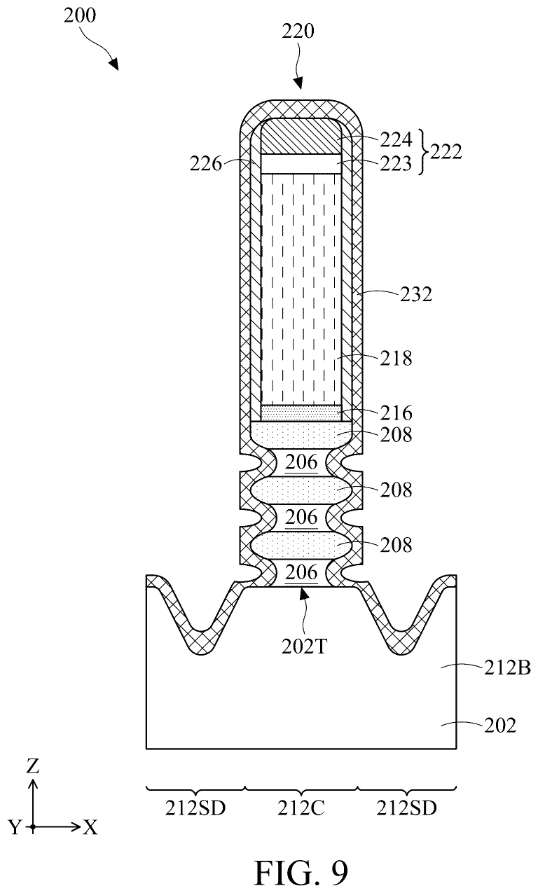

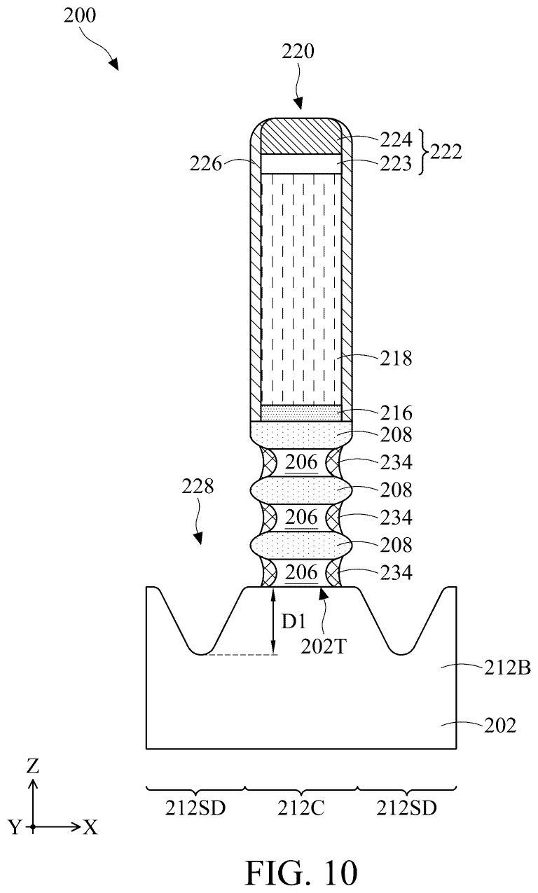

After the inner spacer recesses 230 are formed, the inner spacer material 232 is deposited over the workpiece 200, including over the inner spacer recesses 230, as shown in FIG. 9. While not explicitly shown, the inner spacer material 232 may be a single layer or a multilayer. In some embodiments, at least one layer of the inner spacer material 232 may include a nitride, such as silicon nitride, silicon oxynitride, silicon carbonitride, or silicon oxycarbonitride. In some embodiments, the gate spacers 226 and the inner spacer material 232 include the same material, such as silicon nitride. In some embodiments, the gate spacers 226 and the inner spacer material 232 include different material compositions, such as silicon oxynitride in the gate spacers 226 and silicon nitride in the inner spacer material 232. In some implementations, the inner spacer material 232 may be deposited using CVD, PECVD, SACVD, ALD or other suitable methods. The inner spacer material 232 is deposited into the inner spacer recesses 230 as well as over the sidewalls of the channel layers 208 exposed in the source/drain trenches 228. Referring to FIG. 10, the deposited inner spacer material 232 is then etched back to remove the inner spacer material 232 from the sidewalls of the channel layers 208 to form the inner spacers 234 in the inner spacer recesses 230. At block 112, the inner spacer material 232 may also be removed from the top surfaces and/or sidewalls of the gate-top hard mask layer 222 and the gate spacers 226. In some implementations, the etch back operations performed at block 112 may include use of hydrogen fluoride (HF), fluorine gas (F₂), hydrogen (H₂), ammonia (NH₃), nitrogen trifluoride (NF₃), or other fluorine-based etchants. As shown in FIG. 10, each of the inner spacers 234 is in contact with the recessed sacrificial layers 206 and is disposed between two neighboring channel layers 208. In some instances, each of the inner spacers 234 measures between about 3 nm and about 5 nm thick along the X direction. In the depicted embodiment, each of the inner spacers 234 has a concave sidewall surface facing the respective source/drain trench 228 (i.e., bending inward towards the respective sacrificial layer 206). Alternatively, the sidewall surface may be flat (e.g., substantially vertical) or convex (i.e., bending outward towards the respective source/drain trench 228). As shown in FIG. 10, while the selective etch process and etch back process at block 112 are selective to the sacrificial layers 206 and the inner spacer material 232, the channel layers 208 are moderately etched and have rounded ends. In the depicted embodiment, the source/drain trench 228 extends a depth D1 into the substrate 202 (measured from the plane 202T) and the depth D1 is between about 3 nm and about 115 nm. A width of the source/drain trench 228 (e.g., as measured between opposing sidewalls of the gate spacers 226 on adjacent dummy gate stacks 220 along the X direction) is between about 9 nm to about 32 nm, in some embodiments.

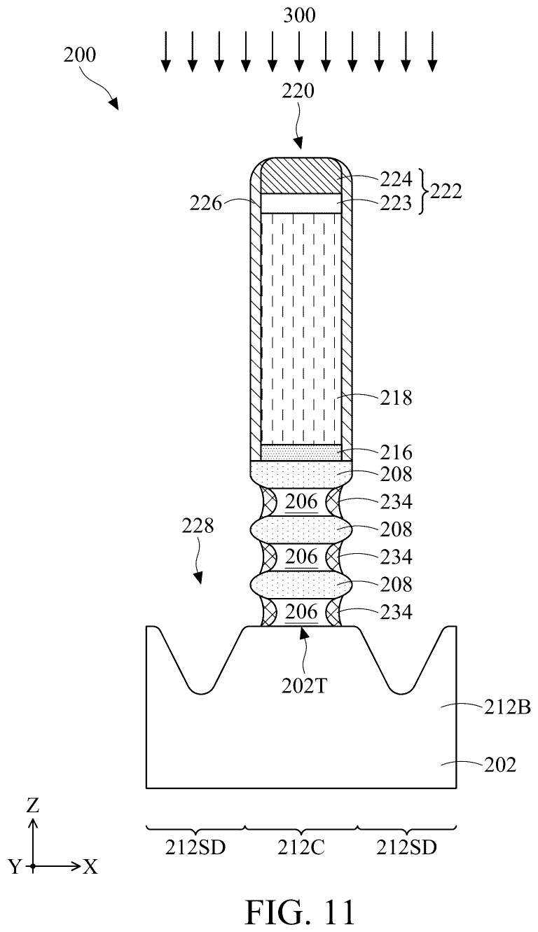

Referring to FIGS. 1 and 11, method 100 includes a block 114 where a cleaning process 300 is performed. The cleaning process 300 may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. In some implementations, the cleaning process is configured to selectively remove or trim a portion of the channel layers without substantially removing the inner spacers 234. The cleaning process 300 may remove surface oxide and debris in order to ensure a clean semiconductor surface, which facilitates growth of a base epitaxial layer at block 116.

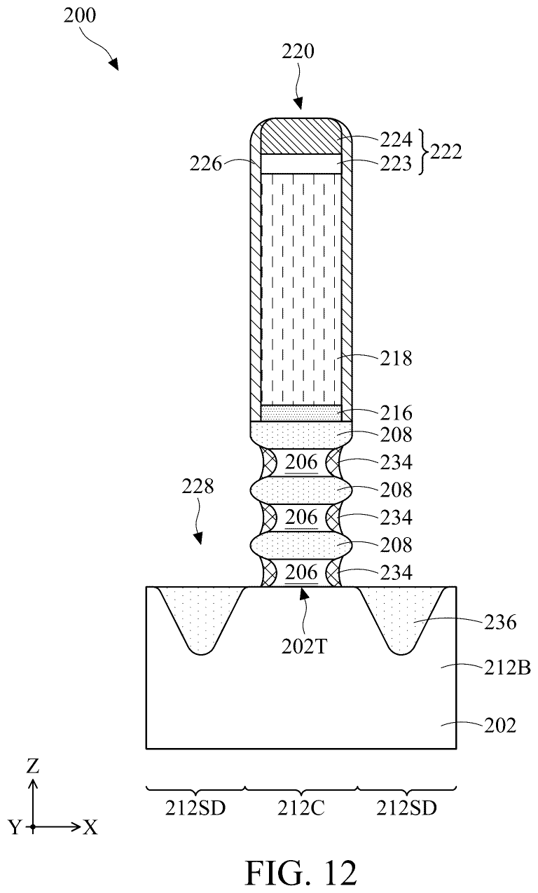

Referring to FIGS. 1 and 12, method 100 includes a block 116 where a base epitaxial layer 236 is deposited in the bottom of the source/drain trench 228. In some embodiments, the base epitaxial layer 236 includes the same material as the substrate 202 and the channel layers 208, such as silicon (Si), except for a dopant condition (doping element and/or doping concentration). For example, the base epitaxial layer 236 is made of non-doped silicon, the substrate 202 is made of doped silicon, and the channel layers 208 are made of non-doped or doped silicon. In some embodiments, the base epitaxial layer 236 includes the same material as the sacrificial layers 206, such as silicon germanium (SiGe), with the germanium (Ge) content the same or different from each other. In various embodiments, the base epitaxial layer 236 is dopant-free, where for example, no intentional doping is performed during the epitaxial growth process. As a comparison, in one instance, the substrate 202 is lightly doped with p-type dopant in the n-type regions for forming n-type transistors and thus has a higher doping concentration than the base epitaxial layer 236. The dopant-free base epitaxial layer 236 provides a high resistance path from the subsequently formed source/drain features to the substrate 202, such that the leakage current into the substrate 202 is suppressed.

Suitable epitaxial processes for block 116 include vapor-phase epitaxy (VPE), molecular beam epitaxy (MBE), selective CVD, and/or other suitable processes. Various deposition parameters can be tuned to selectively deposit the semiconductor material on exposed semiconductor surfaces in the source/drain trenches 228, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the workpiece 200 is exposed to a deposition mixture that includes DCS and/or SiH₄ (silicon-containing precursor), H₂ (carrier precursor), and HCl (etchant-containing precursor) when forming the base epitaxial layer 236. In some embodiments, the selective CVD process implements a deposition temperature of about 600° C. to about 750° C. In some embodiments, the selective CVD process implements a deposition pressure of about 10 Torr to about 100 Torr. In some embodiments, the selective CVD process is configured as a bottom-up deposition process, such that base epitaxial layer 236 grows from the exposed semiconductor surface at the bottom of the source/drain trenches 228, but not from exposed end portions of the channel layers 208. The growth of the base epitaxial layer 236 is under time control such that the top surface of the base epitaxial layer 236 is below the top surface of the fin-shape base 212B (i.e., below the plane 202T). In some embodiments, a post-deposition etch is performed after the selective CVD process to recess the base epitaxial layer 236 below the plane 202T and to remove semiconductor material of the base epitaxial layer 236 that may remain on end portions of the channel layers 208 if any. The post-deposition etch includes a dry etching, a wet etching, other suitable etching process, or combinations thereof. In some embodiments, the top surface of the base epitaxial layer 236 is below the plane 202T for about 2 nm to about 20 nm.

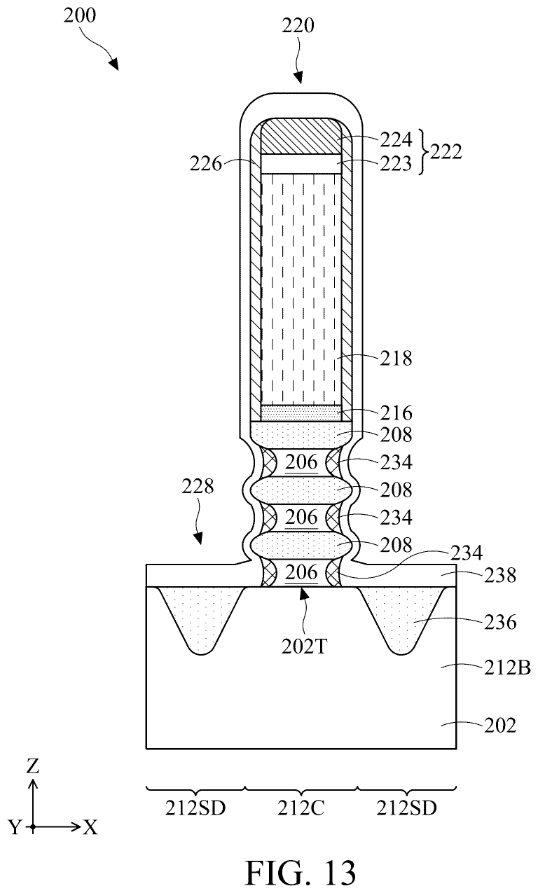

Referring to FIGS. 1, 13, and 14, method 100 includes a block 118 where a dielectric film 240 is formed in the bottom of the source/drain trenches 228 and above the base epitaxial layer 236. While not shown explicitly, operation at block 118 may include deposition of dielectric material 238 over the workpiece 200, and etch back the dielectric material 238 to form the dielectric film 240 in the bottom of the source/drain trenches 228. The dielectric material 238 is deposited over the workpiece 200, including over sidewalls and bottom surfaces of the source/drain trenches 228 and over sidewalls and top surfaces of the dummy gate stack 220, as shown in FIG. 13. In some embodiments, the dielectric material 238 may include a metal oxide or a metal nitride, such as La₂O₃, Al₂O₃, ZnO, ZrN, Zr₂Al₃O₉, TiO₂, TaO₂, ZrO₂, HfO₂, Y₂O₃, AlON, TaCN, other suitable material(s), or combinations thereof. In some embodiments, the dielectric material 238 may include silicon oxide, silicon nitride, silicon oxycarbonitride, silicon nitride, silicon oxynitride, carbon-rich silicon carbonitride, or a low-k dielectric material. In one embodiment, the dielectric material 238 includes a nitride material, such as silicon nitride. The dielectric material 238 is selected such that it has a different etch selectivity from the inner spacers 234, allowing the etching back of the dielectric material 238 without causing etching loss to the inner spacers 234. In some implementations, the dielectric material 238 may be deposited using a directional deposition process, such as PECVD or other suitable methods. The directional deposition process forms the dielectric material 238 with thicker horizontal portions (e.g., on the bottom surface of the source/drain trenches 228 and the top surface of the dummy gate stack 220) and thinner vertical portions (e.g., on sidewalls of the dummy gate stack 220 and the fin-shape structure 212).

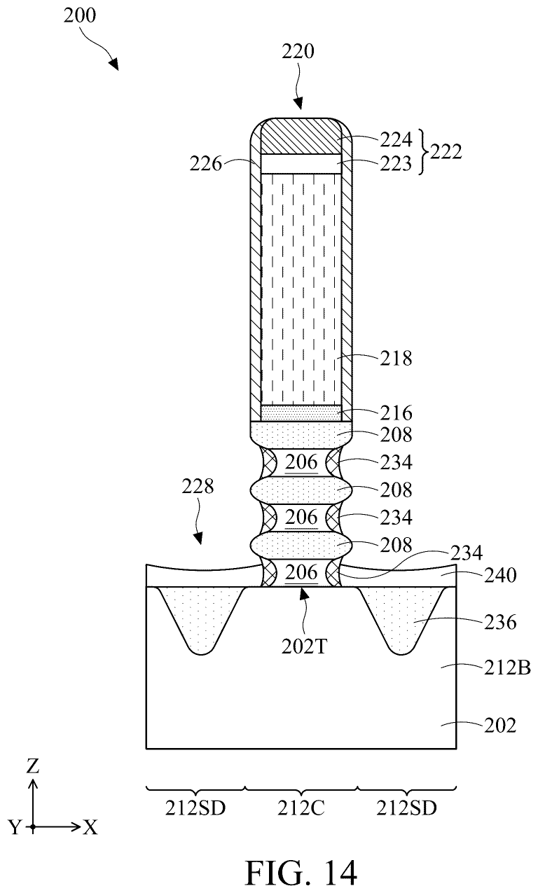

Referring to FIG. 14, the deposited dielectric material 238 is then etched back to remove the thinner vertical portions from the sidewalls of the dummy gate stack 220 and the fin-shape structure 212. In some implementations, the etch back operations performed at block 118 may include use of hydrogen fluoride (HF), fluorine gas (F₂), hydrogen (H₂), ammonia (NH₃), nitrogen trifluoride (NF₃), or other fluorine-based etchants. The thicker horizontal portion atop the dummy gate stack 220 may also be removed due to the loading effect, while the thicker horizontal portion in the bottom of the source/drain trenches 228 is thinned down but still remains as the dielectric film 240, which covers the base epitaxial layer 236. In some embodiments, the dielectric film 240 has a thickness (measured in Z direction) over about 2 nm to about 20 nm, such that a top surface of the dielectric film 240 is about the plane 202T. In the depicted embodiment, the dielectric film 240 is in contact with the bottommost one of the inner spacers 234.

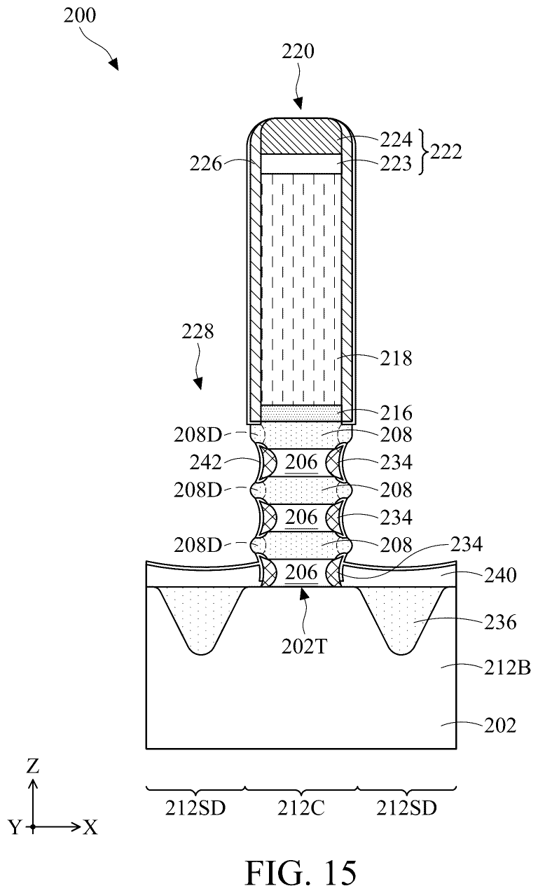

Referring to FIGS. 1 and 15, method 100 includes a block 120 where a segregation preventing layer 242 is selectively deposited on nitride-containing dielectric surfaces. In the depicted embodiment, the segregation preventing layer 242 is an arsenic-containing film. In one example, the segregation preventing layer 242 is essentially made of arsenic atoms in a two-dimensional (2-D) lattice of a single atomic layer or a stack of two, three, or more atomic layers. In another example, arsenic atoms may diffuse into the nitride-containing dielectric surfaces, and the segregation preventing layer 242 is an arsenic-containing compound comprising silicon, nitrogen, arsenic, and/or other suitable elements (e.g., carbon). A thickness of the segregation preventing layer 242 may range from about 0.13 nm to about 1 nm, in some embodiments. The nitride-containing dielectric surface, to where the segregation preventing layer 242 is deposited, includes those exposed surfaces of the gate spacers 226, the inner spacers 234, and the dielectric film 240, and also includes those unexposed surfaces in contact with the channel layers 208, as well as those unexposed surfaces between the bottommost one of the inner spacers 234 and the dielectric film 240. The selective deposition on nitride-containing dielectric surfaces is possible due to arsenic atoms being easily captured by dangling bonds from nitrogen atoms in the nitride-containing dielectric surfaces. In some embodiments, the selective deposition process is performed at a temperature between about 450°° C. and about 800° C., under a pressure between about 5 Torr and about 600 Torr, and with a carrier gas (e.g., an inert gas) and an arsenic-containing process gas (e.g., arsine (AsH₃)). On the exposed nitride-containing dielectric surfaces, arsenic atoms would be directly captured by the dangling bonds; further, some arsenic atoms may diffuse along the interface between the nitride-containing dielectric surfaces and the semiconductor (e.g., Si) surfaces of the channel layers 208 and are captured by dangling bonds of those unexposed nitride-containing dielectric surfaces. Accordingly, the arsenic-containing segregation preventing layer 242 is formed on exposed surfaces of the gate spacers 226, the inner spacers 234, and the dielectric film 240, and also on unexposed surfaces interfacing the channel layers 208, as well as those unexposed surfaces between the bottommost one of the inner spacers 234 and the dielectric film 240. Further, the portion of the segregation preventing layer 242 formed on the exposed surfaces may be thicker than other portion of the segregation preventing layer 242 formed on the unexposed surfaces.

Other than the arsenic atoms in forming the segregation preventing layer 242, there are also some arsenic atoms diffuse into end portions of the channel layers 208 forming lightly doped regions 208D. The lightly doped regions 208D are positioned at the terminal ends of the channel layers 208. In some embodiments, the lightly doped regions 208D include an arsenic (As) content between about 2% and about 10% atomic percentage and a silicon (Si) content between about 98% and about 90% atomic percentage.

Notably, the arsenic-containing segregation preventing layer 242 represents one embodiment of the segregation preventing layer 242. A segregation preventing layer composed of other materials that effectively reduce dangling bonds on a nitride-containing dielectric surface is also contemplated in this disclosure.

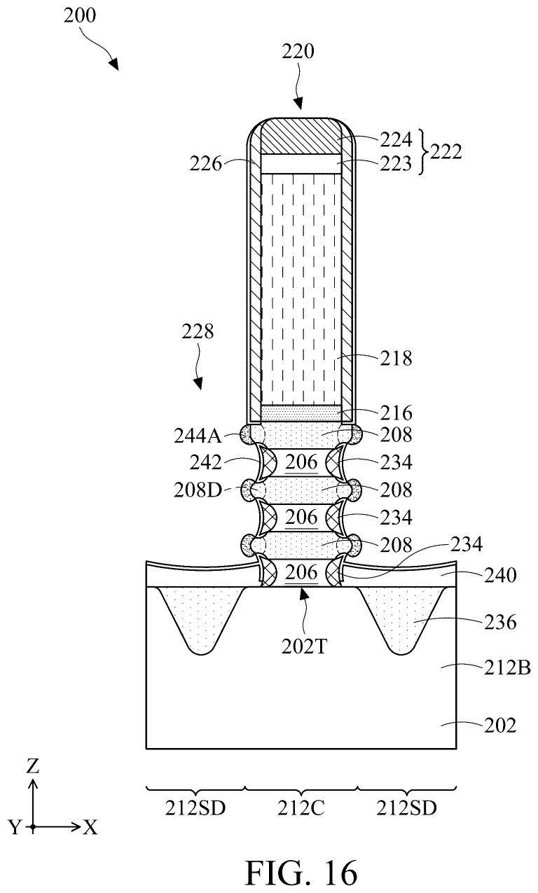

Referring to FIGS. 1 and 16, method 100 includes a block 122 where a first epitaxial layer 244A is deposited on the rounded ends of channel layers 208. The first epitaxial layer 244A wraps over the rounded ends and has a curved shape. In these embodiments, the first epitaxial layer 244A is formed to a thickness such that the rounded ends are completely covered. In some instances, the first epitaxial layer 244A has a thickness between about 1 nm and about 6 nm along the X direction. The first epitaxial layer 244A may be epitaxially and selectively formed from the exposed sidewalls of the channel layers 208 while sidewalls of the sacrificial layers 206 remain covered by the inner spacers 234. Suitable epitaxial processes for block 122 include vapor-phase epitaxy (VPE), ultra-high vacuum CVD (UHV-CVD), molecular beam epitaxy (MBE), and/or other suitable processes. The epitaxial growth process at block 122 may use gaseous precursors, which interact with the composition of the channel layers 208. According to the present disclosure, upon conclusion of the operations at block 122, at least some inner spacers 234 remain exposed. That is, at least some inner spacers 234 are not completely covered by the first epitaxial layer 244A. The first epitaxial layer 244A is in contact with the segregation preventing layer 242. The segregation preventing layer 242 separates the first epitaxial layer 244A from contacting the inner spacers 234.

In some instances, the first epitaxial layer 244A includes silicon arsenic (SiAs). In some embodiments, the first epitaxial layer 244A includes an arsenic (As) content between about 10% and about 40% atomic percentage and a silicon (Si) content between about 90% and about 60% atomic percentage. This arsenic (As) content range is not trivial. When the arsenic content is greater than about 40%, the lattice mismatch between silicon and arsenic may cause too much defect at the interface between the first epitaxial layer 244A and the channel layers 208, which may lead to increased resistance or device failure. When the arsenic content is smaller than about 10%, the channel layers 208 may not be sufficiently strained for improved carrier mobility. The arsenic content in the first epitaxial layer 244A is higher than in the lightly doped regions 208D.

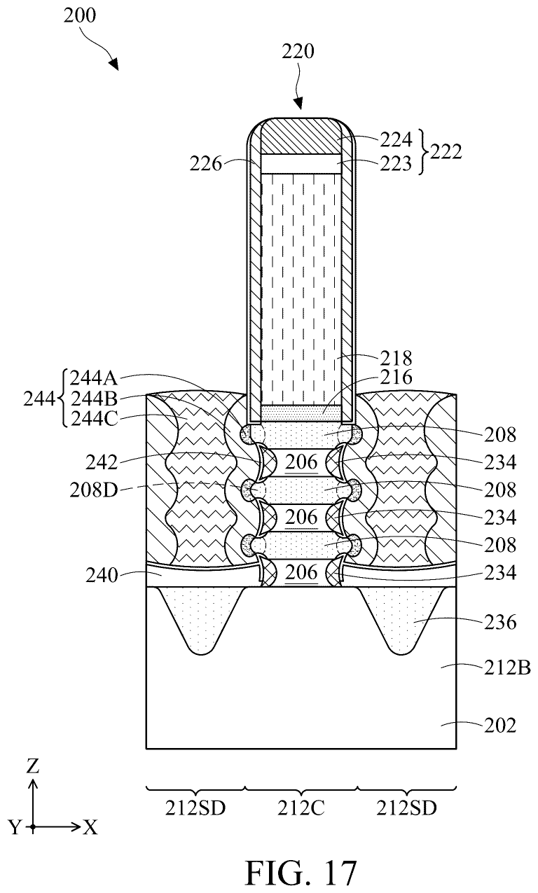

Referring to FIGS. 1 and 17, method 100 includes a block 124 where a second epitaxial layer 244B is deposited over the first epitaxial layer 244A, and a third epitaxial layer 244C is deposited over the second epitaxial layer 244B. The epitaxial layers 244A, 244B, and 244C are collectively referred to as epitaxial features 244. The epitaxial features 244 are also referred to as source/drain features, or source/drain epitaxial features. The epitaxial features 244 land on the horizontal portion of the segregation preventing layer 242 deposited on the top surface of the dielectric film 240. Suitable epitaxial processes for block 124 include vapor-phase epitaxy (VPE), ultra-high vacuum CVD (UHV-CVD), molecular beam epitaxy (MBE), and/or other suitable processes. The epitaxial growth process at block 124 may use gaseous precursors, which interact with the composition of the first epitaxial layer 244A. The second epitaxial layer 244B is allowed to overgrow and merge over the inner spacers 234 and in contact with the segregation preventing layer 242 on the inner spacers 234; the third epitaxial layer 244C substantially fills the source/drain trenches 228. A top surface of the third epitaxial layer 244C may grow above the top surface of the fin-shape structure 212 (i.e., the top surface of the topmost channel layer 208) and intersect the segregation preventing layer 242 on sidewalls of the gate spacers 226. In some embodiments, the second epitaxial layer 244B and the third epitaxial layer 244C each include silicon (Si) doped with phosphorus (P) but differ in concentrations. The third epitaxial layer 244C serves as a low resistance layer and includes a doping concentration greater than that in the second epitaxial layer 244B. In some instances, the doping concentration in the third epitaxial layer 244C may be between about 1×10²⁰ atoms/cm³ and about 3×10²¹ atoms/cm³, while the doping concentration in the second epitaxial layer 244B may be between about 0.5×10²⁰ atoms/cm³ and about 1×10²⁰ atoms/cm³. Some phosphorus atoms would diffuse through the first epitaxial layer 244A and into the lightly doped region 208D. Therefore, the lightly doped region 208D includes two n-type dopants, arsenic (As) and phosphorus (P).

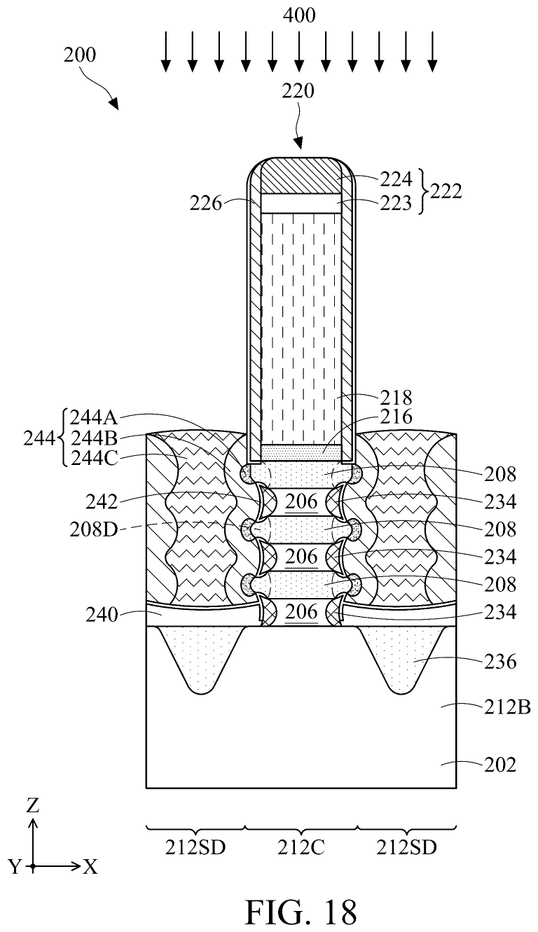

Referring to FIGS. 1 and 18, method 100 includes a block 126 where the workpiece 200 is annealed in an anneal process 400. In some implementation, the anneal process 400 may include a rapid thermal anneal (RTA) process, a laser spike anneal process, a flash anneal process, or a furnace anneal process. The anneal process 400 may include a peak anneal temperature between about 900° C. and about 1000° C. In these implementations, the peak anneal temperature may be maintained for a duration measured by seconds or microseconds. Through the anneal process 400, a desired electronic contribution of the n-type dopants in the semiconductor host, such as silicon arsenic (SiAs) or silicon (Si), may be obtained. The anneal process 400 may generate vacancies that facilitate movement of dopants from interstitial sites to substitutional lattice sites and reduce damages or defects in the lattice of the semiconductor host.

The anneal process 400 also accelerates more phosphorus atoms to diffuse through the first epitaxial layer 244A and into the lightly doped region 208D. The lightly doped region 208D further expands laterally towards the center of the channel region. The region 208D as being doped is similar to an extension from the source/drain region, therefore the lightly doped region 208D is also referred to as the source/drain extension (SDE) region 208D. In one embodiment, a concentration of arsenic is less than phosphorus in the SDE region 208D. In another embodiment, a concentration of arsenic is larger than phosphorus in the SDE region 208D. The SDE region 208D does not extend beyond the inner spacers 234 in the X direction to avoid in direct contact with the sacrificial layers 206. Although the SDE region 208D is stacked between the nitride-containing dielectric surfaces of adjacent inner spacers 234, the segregation preventing layer 242 blocks phosphorus atoms from being clustered or segregated on the nitride-containing dielectric surface. Thus, a concentration of active phosphorus is increased in the SDE region 208D, which improves drive current capability. A junction profile (represented by dotted curved lines in FIG. 18) of the SDE region 208D is also more evenly distributed, which improves device performance uniformity.

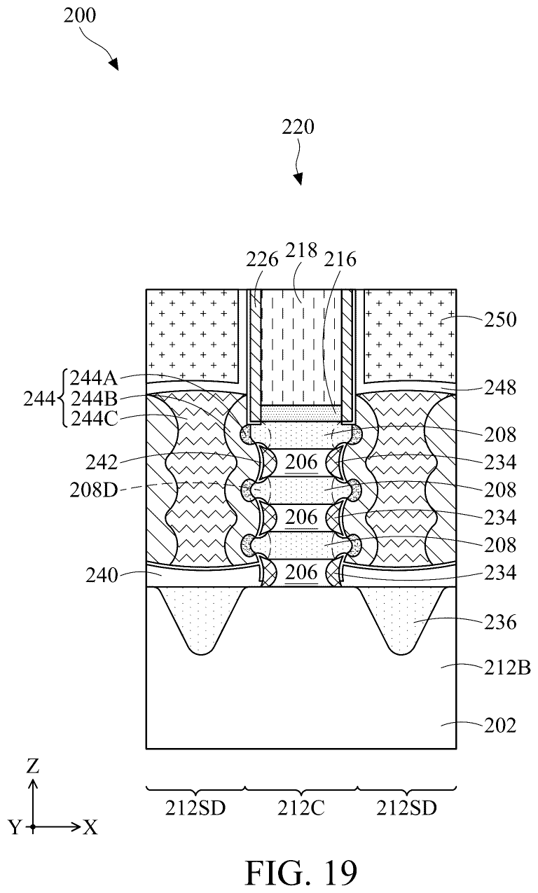

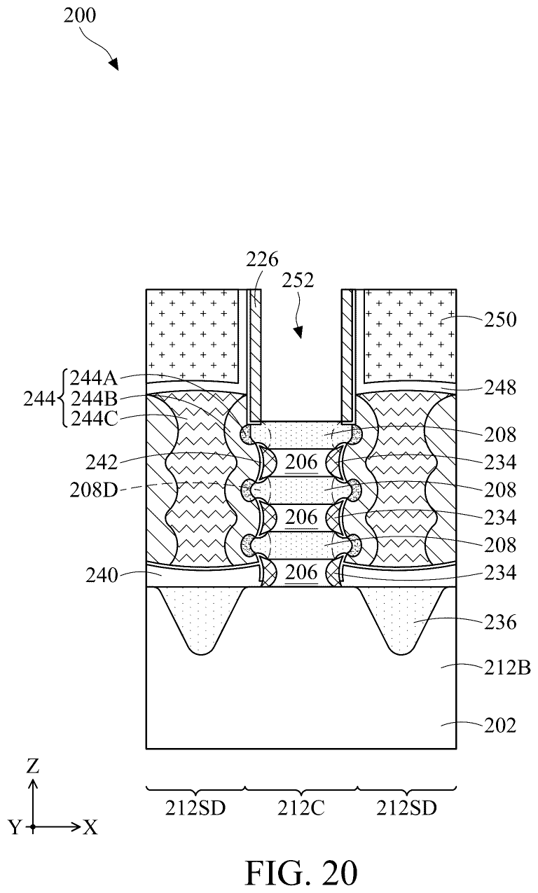

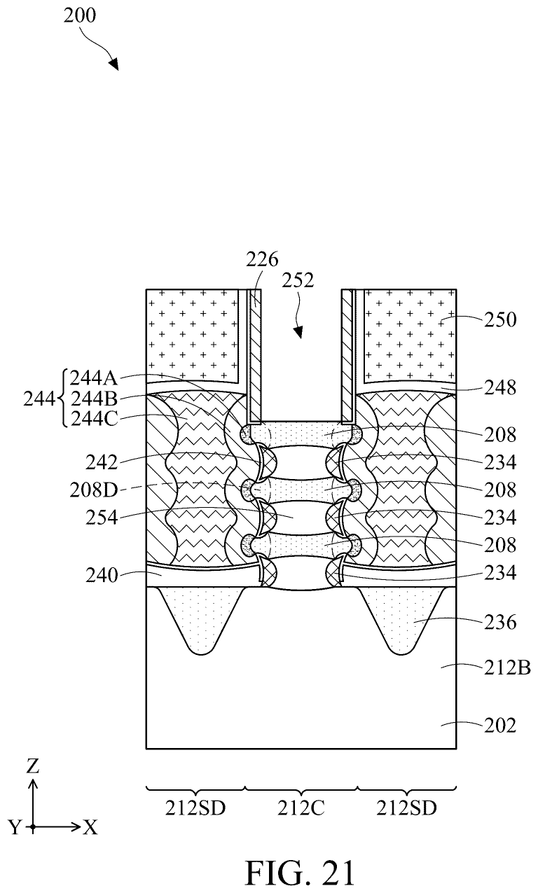

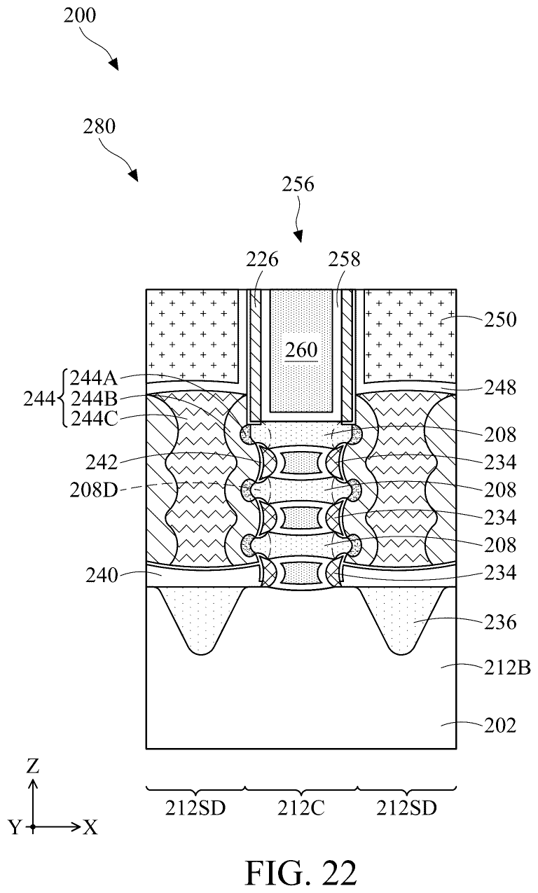

Referring to FIGS. 1 and 19-22, method 100 includes a block 128 where further processes are performed. Such further processes may include, for example, deposition of a contact etch stop layer (CESL) 248 over the workpiece 200 (shown in FIG. 19), deposition of an interlayer dielectric (ILD) layer 250 over the CESL 248 (shown in FIG. 19), removal of the dummy gate stack 220 (shown in FIG. 20), selective removal of the sacrificial layers 206 in the channel region 212C to release the channel layers 208 as channel members (shown in FIG. 21), and formation of a gate structure 256 over the channel region 212C (shown in FIG. 22). Referring now to FIG. 19, the CESL 248 is formed prior to forming the ILD layer 250. In some examples, the CESL 248 includes silicon nitride, silicon oxynitride, and/or other materials known in the art. The CESL 248 may be formed by ALD, plasma-enhanced chemical vapor deposition (PECVD) process and/or other suitable deposition processes. The ILD layer 250 is then deposited over the CESL 248. In some embodiments, the ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be deposited by a PECVD process or other suitable deposition technique. In some embodiments, after formation of the ILD layer 250, the workpiece 200 may be annealed to improve integrity of the ILD layer 250. As shown in FIG. 19, the CESL 248 is disposed directly on top surfaces of the source/drain features 244.

Referring to FIGS. 19 and 20, after the deposition of the CESL 248 and the ILD layer 250, the workpiece 200 may be planarized by a planarization process to expose the dummy gate stack 220. For example, the planarization process may include a chemical mechanical planarization (CMP) process. After the CMP process, a distance from the top surface of the dummy gate stack 220 to the top surface of the topmost channel layer 208 may measure between 5 nm and about 50 nm along the Z direction. Exposure of the dummy gate stack 220 allows the removal of the dummy gate stack 220 and release of the channel layers 208, illustrated in FIG. 20. In some embodiments, the removal of the dummy gate stack 220 results in a gate trench 252 over the channel regions 212C. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed in the gate trench 252. Further, the portion of the segregation preventing layer 242 being stacked between the gate spacers 226 and the topmost one of the channel layers 208 may also be exposed in the gate trench 252.

Referring to FIG. 21, after the removal of the dummy gate stack 220, method 100 includes operations to selectively remove the sacrificial layers 206 between the channel layers 208 in the channel region 212C. The selective removal of the sacrificial layers 206 releases the channel layers 208 to form channel members (also numbered as 208). The selective removal of the sacrificial layers 206 also leaves behind space 254 between channel members 208. The space 254 can be considered as a portion of the gate trench 252 that extends continuously downward below the bottommost one of the channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Further, the portion of the segregation preventing layer 242 being stacked between the inner spacers 234 and the channel members 208 may also be exposed in the space 254.

Referring to FIG. 22, method 100 includes further operations to form the gate structure 256 to wrap around each of the channel members 208. In some embodiments, the gate structure 256 is formed within the gate trench 252 (and into the space 254 left behind by the removal of the sacrificial layers 206). In this regard, the gate structure 256 wraps around each of the channel members 208. The gate structure 256 includes a gate dielectric layer 258 and a gate electrode layer 260 over the gate dielectric layer 258. In some embodiments, while not explicitly shown in the figures, the gate dielectric layer 258 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods. Further, the exposed ends of the segregation preventing layer 242 may be in contact with the gate dielectric layer 258, particularly the interfacial layer. If the interfacial layer is thinner than the segregation preventing layer 242, the segregation preventing layer 242 may be in contact with both the interfacial layer and the high-k gate dielectric layer.

The gate electrode layer 260 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 260 may include titanium nitride (TiN), titanium aluminum (TiAl), titanium aluminum nitride (TiAlN), tantalum nitride (TaN), tantalum aluminum (TaAl), tantalum aluminum nitride (TaAIN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 260 may be formed by ALD, PVD, CVD, e-beam evaporation, or other suitable process. In various embodiments, a CMP process may be performed to remove excessive metal, thereby providing a substantially planar top surface of the gate structure 256. The gate structure 256 includes portions that interpose between channel members 208 in the channel region 212C.

Still referring to FIG. 22, upon conclusion of the operations at block 128, a transistor 280, particularly an n-type transistor 280, is substantially formed. The transistor 280 includes channel members 208 that are vertically stacked along the Z direction. Each of the channel members 208 is wrapped around by the gate structure 256. The channel members 208 extend or are sandwiched between two source/drain features 244 along the X direction. Each of the source/drain features 244 includes the first epitaxial layer 244A in contact with the channel members 208, the second epitaxial layer 244B in contact with the first epitaxial layer 244A, and the third epitaxial layer 244C in contact with the second epitaxial layer 244B. The second epitaxial layer 244B is spaced apart from the channel members 208 by the first epitaxial layer 244A. The first epitaxial layer 244A may include SiAs, the second and third epitaxial layers 244B and 244C may include SiP. The phosphorus atoms also diffuse into the first epitaxial layer 244A and into the end portions of the channel members 208 in forming SDE regions 208D stacked between inner spacers 234. The arsenic-containing segregation preventing layer 242 separates the SEC regions 208D from contacting the inner spacers 234 and the gate spacers 226, retarding the phosphorus segregation.

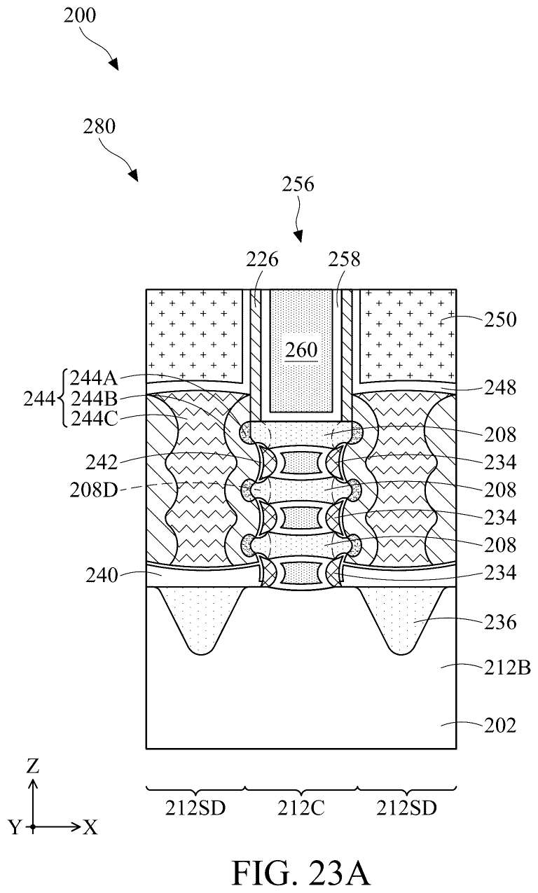

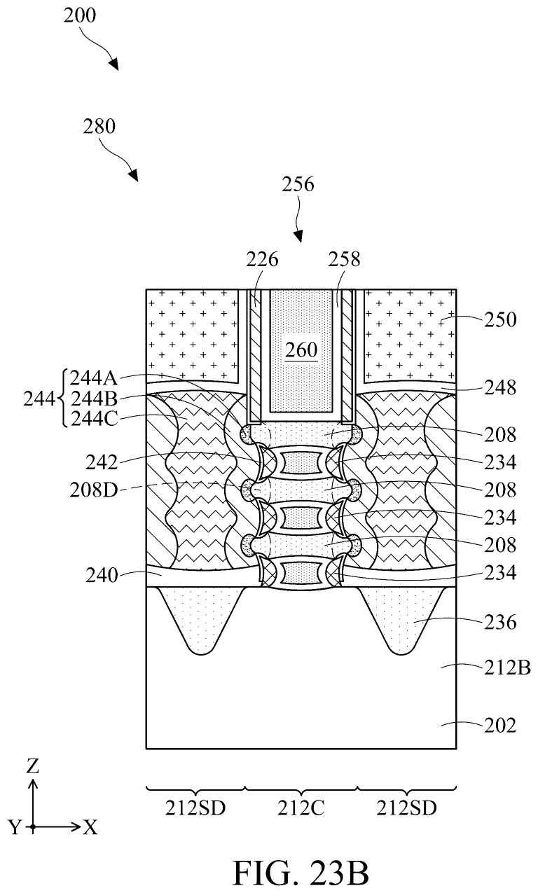

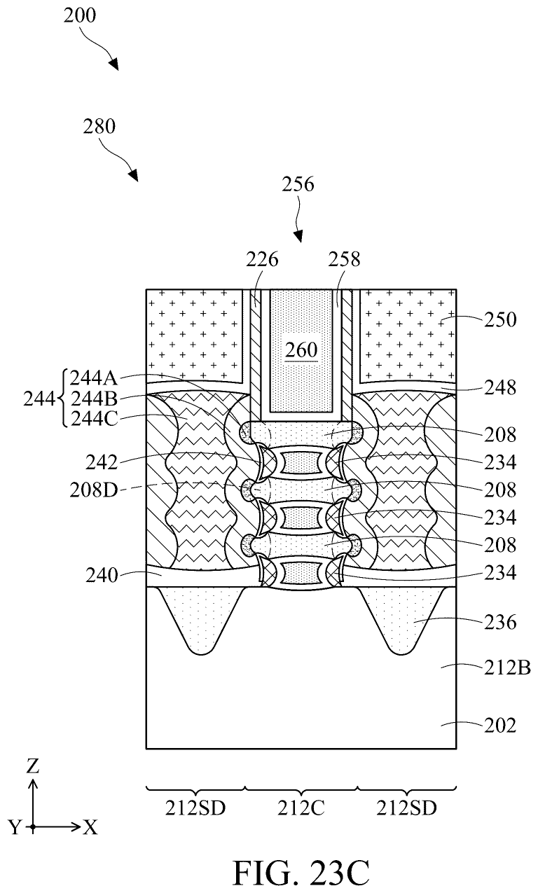

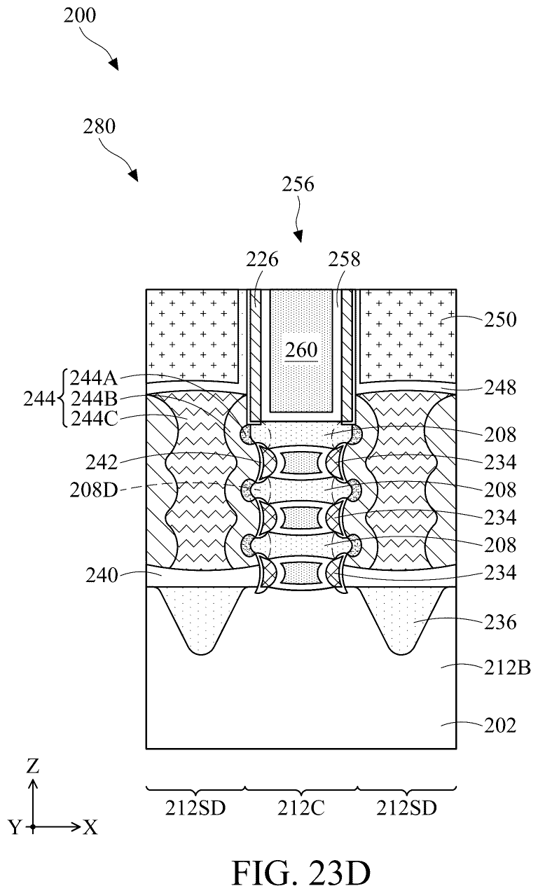

An alternative embodiment of the transistor 280 is illustrated in FIG. 23A. Many aspects of the transistors 280 in FIGS. 22 and 23A are the same or similar. For clarity and ease of reference, reference numerals for the same or similar features are repeated. One difference is that for the depicted embodiment as in FIG. 23A, the gate spacers 226 may be formed of a dielectric material other than nitride (e.g., an oxide), therefore lack of dangling bonds in capturing arsenic atoms. Therefore, the selective deposition process may form the segregation preventing layer 242 on surfaces of the inner spacers 234 and the dielectric film 240 but not on surfaces of the gate spacers 226.

An alternative embodiment of the transistor 280 is illustrated in FIG. 23B. Many aspects of the transistors 280 in FIGS. 22 and 23B are the same or similar. For clarity and ease of reference, reference numerals for the same or similar features are repeated. One difference is that for the depicted embodiment as in FIG. 23B, the dielectric film 240 may be formed of a dielectric material other than nitride (e.g., an oxide), therefore lack of dangling bonds in capturing arsenic atoms. Therefore, the selective deposition process may form the segregation preventing layer 242 on surfaces of the inner spacers 234 and the gate spacers 226 but not on surfaces of the dielectric film 240.

An alternative embodiment of the transistor 280 is illustrated in FIG. 23C. Many aspects of the transistors 280 in FIGS. 22 and 23C are the same or similar. For clarity and ease of reference, reference numerals for the same or similar features are repeated. One difference is that for the depicted embodiment as in FIG. 23C, the gate spacers 226 and the dielectric film 240 each may be formed of a dielectric material other than nitride (e.g., an oxide), therefore lack of dangling bonds in capturing arsenic atoms. Therefore, the selective deposition process may form the segregation preventing layer 242 on surfaces of the inner spacers 234 but not on surfaces of the gate spacers 226 and the dielectric film 240.

An alternative embodiment of the transistor 280 is illustrated in FIG. 23D. Many aspects of the transistors 280 in FIGS. 22 and 23D are the same or similar. For clarity and ease of reference, reference numerals for the same or similar features are repeated. One difference is that for the depicted embodiment as in FIG. 23D, the selective deposition of the segregation preventing layer 242 is performed prior to the formation of the base epitaxial layer 236 and the dielectric film 240 (block 120 prior to blocks 116 and 118 in FIG. 1), such that the segregation preventing layer 242 is also formed on the interface between the bottommost one of the inner spacers 234 and the dielectric film 240 and on the interface between the bottommost one of the inner spacers 234 and the fin-shape base 212B. Since in this alternative embodiment, the dielectric film 240 is formed after the selective deposition of the segregation preventing layer 242, no segregation preventing layer 242 is formed on the top surface of the dielectric film 240 regardless of whether the dielectric film 240 is a nitride, an oxide, or other dielectric material. Yet, whether the segregation preventing layer 242 is deposited on the surfaces of the gate spacers 226 relies on whether the gate spacers 226 is a nitride, as variations depicted in FIG. 23A.

Although not intended to be limiting, one or more embodiments of the present disclosure provide many benefits to a semiconductor device and the formation thereof. For example, embodiments of the present disclosure provide a transistor, particularly an n-type transistor, that includes a vertical stack of the channel members extending between two source/drain features. The source/drain features are spaced apart from the inner spacers and/or gate spacers by a segregation preventing layer. The segregation preventing layer retards the phosphorus segregation, increases the active phosphorus concentration in SDE regions, and improves junction profile uniformity.

In one exemplary aspect, the present disclosure is directed to a method. The method includes forming a stack over a substrate, the stack comprising a plurality of channel layers interleaved by a plurality of sacrificial layers, patterning the stack and a top portion of the substrate to form a fin-shape structure, the fin-shape structure comprising a channel region and a source/drain region, forming a dummy gate stack over the channel region of the fin-shape structure, depositing gate spacers on sidewalls of the dummy gate stack, recessing the source/drain region to form a source/drain trench that exposes sidewalls of the channel layers and the sacrificial layers, partially recessing the sacrificial layers to form a plurality of inner spacer recesses, forming a plurality of inner spacers in the inner spacer recesses, the inner spacers each including a first surface exposed in the source/drain trench and a second surface facing an adjacent one of the channel layers, selectively depositing a segregation preventing layer on the first and second surfaces of the inner spacers, forming an epitaxial feature in the source/drain trench, a portion of the segregation preventing layer stacked between the inner spacers and the epitaxial feature, after the forming of the epitaxial feature, removing the dummy gate stack, releasing the channel layers in the channel region as a plurality of channel members, and forming a gate structure wrapping around each of the channel members. In some embodiments, the segregation preventing layer includes arsenic. In some embodiments, the segregation preventing layer is a two-dimensional (2-D) lattice of a single atomic layer. In some embodiments, the segregation preventing layer is an arsenic-containing compound. In some embodiments, the segregation preventing layer has a thickness ranging from about 0.13 nm to about 1 nm. In some embodiments, the segregation preventing layer separates the epitaxial feature from contacting the inner spacers. In some embodiments, the selectively depositing of the segregation preventing layer also deposits the segregation preventing layer on sidewalls of the gate spacers. In some embodiments, the forming of the epitaxial feature includes forming a first epitaxial layer in contact with the channel layers, and forming a second epitaxial layer over the first epitaxial layer and in contact with the segregation preventing layer. The first epitaxial layer includes a first n-type dopant, and the second epitaxial layer includes a second n-type dopant different from the first n-type dopant. In some embodiments, the first n-type dopant is arsenic, the second n-type dopant is phosphorus, and the segregation preventing layer includes arsenic. In some embodiments, during the selectively depositing of the segregation preventing layer, the segregation preventing layer is selectively deposited on nitride-containing dielectric surfaces, and wherein the inner spacers include a nitride.

In another exemplary aspect, the present disclosure is directed to a method. The method includes forming a plurality of channel members disposed over a fin-shape substrate, forming a plurality of inner spacers interleaving the channel members, the inner spacers including a nitride, depositing an arsenic-containing layer on sidewalls of the inner spacers, forming an epitaxial feature abutting the channel members, the arsenic-containing layer stacked between the epitaxial feature and the inner spacers, and forming a gate structure wrapping around each of the channel members. In some embodiments, the gate structure includes a gate dielectric layer and a gate electrode layer, and the arsenic-containing layer is in contact with the gate dielectric layer. In some embodiments, the forming of the epitaxial feature includes forming a first epitaxial layer abutting the channel members, the first epitaxial layer including arsenic, and forming a second epitaxial layer over the first epitaxial layer, the second epitaxial layer substantially free of arsenic. In some embodiments, a portion of the arsenic-containing layer is vertically stacked between the inner spacers and the channel members. In some embodiments, the method further includes forming a dielectric layer interposing a bottom surface of the epitaxial feature and a top surface of the fin-shape substrate. The arsenic-containing layer interposes the bottom surface of the epitaxial feature and a top surface of the dielectric layer. In some embodiments, the arsenic-containing layer separates the epitaxial feature from contacting the inner spacers.

In yet another exemplary aspect, the present disclosure is directed to a semiconductor device. The semiconductor device includes a fin-shape base protruding from a substrate, a plurality of channel members disposed over a top surface of the fin-shape base, a plurality of inner spacers interleaving the channel members, a gate structure wrapping around each of the channel members, gate spacers disposed on sidewalls of the gate structure, a source/drain feature abutting the channel members, and an arsenic-containing film interposing the source/drain feature and the inner spacers. In some embodiments, the arsenic-containing film also interposes the inner spacers and the channel members. In some embodiments, the arsenic-containing film has a first thickness measured between the source/drain feature and the inner spacers and a second thickness measured between the inner spacers and the channel members, and the first thickness is larger than the second thickness. In some embodiments, the semiconductor device further includes a dielectric film interposing the substrate and the source/drain feature. The arsenic-containing film also interposes the dielectric film and the source/drain feature.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack over a substrate, the stack comprising a plurality of channel layers interleaved by a plurality of sacrificial layers;
patterning the stack and a top portion of the substrate to form a fin-shape structure, the fin-shape structure comprising a channel region and a source/drain region;
forming a dummy gate stack over the channel region of the fin-shape structure;
depositing gate spacers on sidewalls of the dummy gate stack;
recessing the source/drain region to form a source/drain trench that exposes sidewalls of the channel layers and the sacrificial layers;
partially recessing the sacrificial layers to form a plurality of inner spacer recesses;
forming a plurality of inner spacers in the inner spacer recesses, wherein the inner spacers each include a first surface exposed in the source/drain trench and a second surface facing an adjacent one of the channel layers;
selectively depositing a segregation preventing layer on the first and second surfaces of the inner spacers;
forming an epitaxial feature in the source/drain trench, wherein a portion of the segregation preventing layer is stacked between the inner spacers and the epitaxial feature;
after the forming of the epitaxial feature, removing the dummy gate stack;
releasing the channel layers in the channel region as a plurality of channel members; and
forming a gate structure wrapping around each of the channel members.

2. The method of claim 1, wherein the segregation preventing layer includes arsenic.

3. The method of claim 2, wherein the segregation preventing layer is a two-dimensional (2-D) lattice of a single atomic layer.

4. The method of claim 2, wherein the segregation preventing layer is an arsenic-containing compound.

5. The method of claim 1, wherein the segregation preventing layer has a thickness ranging from about 0.13 nm to about 1 nm.

6. The method of claim 1, wherein the segregation preventing layer separates the epitaxial feature from contacting the inner spacers.

7. The method of claim 1, wherein the selectively depositing of the segregation preventing layer also deposits the segregation preventing layer on sidewalls of the gate spacers.

8. The method of claim 1, wherein the forming of the epitaxial feature includes:
forming a first epitaxial layer in contact with the channel layers; and
forming a second epitaxial layer over the first epitaxial layer and in contact with the segregation preventing layer,
wherein the first epitaxial layer includes a first n-type dopant, and the second epitaxial layer includes a second n-type dopant different from the first n-type dopant.

9. The method of claim 8, wherein the first n-type dopant is arsenic, the second n-type dopant is phosphorus, and the segregation preventing layer includes arsenic.

10. The method of claim 1, wherein during the selectively depositing of the segregation preventing layer, the segregation preventing layer is selectively deposited on nitride-containing dielectric surfaces, and wherein the inner spacers include a nitride.

11. A method, comprising:
forming a plurality of channel members disposed over a fin-shape substrate;
forming a plurality of inner spacers interleaving the channel members, wherein the inner spacers include a nitride;
depositing an arsenic-containing layer on sidewalls of the inner spacers;
forming an epitaxial feature abutting the channel members, wherein the arsenic-containing layer is stacked between the epitaxial feature and the inner spacers; and
forming a gate structure wrapping around each of the channel members.

12. The method of claim 11, wherein the gate structure includes a gate dielectric layer and a gate electrode layer, and wherein the arsenic-containing layer is in contact with the gate dielectric layer.

13. The method of claim 11, wherein the forming of the epitaxial feature includes:
forming a first epitaxial layer abutting the channel members, wherein the first epitaxial layer includes arsenic; and
forming a second epitaxial layer over the first epitaxial layer, wherein the second epitaxial layer is substantially free of arsenic.

14. The method of claim 11, wherein a portion of the arsenic-containing layer is vertically stacked between the inner spacers and the channel members.

15. The method of claim 11, further comprising:
forming a dielectric layer interposing a bottom surface of the epitaxial feature and a top surface of the fin-shape substrate,
wherein the arsenic-containing layer interposes the bottom surface of the epitaxial feature and a top surface of the dielectric layer.

16. The method of claim 11, wherein the arsenic-containing layer separates the epitaxial feature from contacting the inner spacers.

17. A semiconductor device, comprising:
a fin-shape base protruding from a substrate;
a plurality of channel members disposed over a top surface of the fin-shape base;
a plurality of inner spacers interleaving the channel members;
a gate structure wrapping around each of the channel members;
gate spacers disposed on sidewalls of the gate structure;
a source/drain feature abutting the channel members; and
an arsenic-containing film interposing the source/drain feature and the inner spacers.

18. The semiconductor device of claim 17, wherein the arsenic-containing film also interposes the inner spacers and the channel members.

19. The semiconductor device of claim 18, wherein the arsenic-containing film has a first thickness measured between the source/drain feature and the inner spacers and a second thickness measured between the inner spacers and the channel members, and wherein the first thickness is larger than the second thickness.

20. The semiconductor device of claim 17, further comprising:
a dielectric film interposing the substrate and the source/drain feature, wherein the arsenic-containing film also interposes the dielectric film and the source/drain feature.
